(19) United States
(12) Patent Application Publication
(10) Pub. No.: US 2026/0331429 A1
(43) Pub. Date: Oct. 22, 2026

(54) RADIO FREQUENCY GENERATOR SYSTEM AND PLASMA GENERATION SYSTEM FOR PLASMA EXCITATION FOR A PLASMA PROCESS AND METHOD OF EXCITING A PLASMA FOR A PLASMA PROCESS

(71) Applicant: Rohde & Schwarz GmbH & Co. KG, Muenchen (DE)

(72) Inventors: Harald SPECKER, Muenchen (DE); Wolfram TITZE, Muenchen (DE); Florian OHNIMUS, Muenchen (DE)

(21) Appl. No.: 19/353,924

(22) Filed: Oct. 9, 2025

(30) Foreign Application Priority Data
Nov. 29, 2024 (DE) 10 2024 135 386.4

(51) Int. Cl. H01J 37/32; H03H 7/38

(52) U.S. Cl. CPC H01J 37/32183; H03H 7/38

(57) ABSTRACT

A radio frequency generator system for plasma excitation for a plasma process includes a signal generator unit configured to generate at least three radio frequency signals having different frequencies. The system also includes a broadband amplifier stage configured to amplify the radio frequency signals to output amplified radio frequency signals at an amplifier stage output of the amplifier stage. The system further includes a matching network that is configured to set a predefined impedance for the amplifier stage output of the amplifier stage, the impedance between the amplifier stage output and the matching network being different than (e.g., not equal to) 50 ohms. The system also includes a plasma process impedance acquisition unit configured to acquire a complex-valued impedance of the plasma process, and a control unit configured to control the signal generator unit, the amplifier stage, and/or the matching network based on the acquired complex-valued impedance.

### CROSS-REFERENCE(S) TO RELATED APPLICATION(S)

This application claims priority to German Application No. 10 2024 135 386.4, filed on Nov. 29, 2024, the entire disclosure of which is incorporated herein in its entirety.

### TECHNICAL FIELD OF THE DISCLOSURE

Embodiments of the present disclosure relate to a radio frequency generator system for plasma excitation for a plasma process. Further, embodiments of the present disclosure relate to a plasma generation system for plasma excitation for a plasma process. Embodiments of the present disclosure also relate to a method of exciting a plasma for a plasma process.

### BACKGROUND

Plasma generation systems that include a plasma process chamber and a signal generator for radio frequency plasma applications are disclosed in the prior art. Typically, the signal generator is connected to the plasma process chamber by a separately designed matching network, which is also referred to as a match-box. The matching network protects the signal generator from mismatching.

However, it has turned out to be a drawback of the solutions known from the prior art that the matching network, which serves to protect the signal generator from mismatching, causes additional power losses, resulting in reduced efficiency of the plasma generation system.

There is a need to increase the efficiency of a plasma generation system.

### SUMMARY

Embodiments of the present disclosure provide a radio frequency generator system for plasma excitation for a plasma process. In an embodiment, the system includes a signal generator unit configured to generate at least three radio frequency signals having different frequencies. The signal generator unit has a shared signal generator output through which the radio frequency signals are output. The radio frequency generator system also includes a broadband amplifier stage which is connected to the shared signal generator output and is configured to amplify the radio frequency signals to output amplified radio frequency signals at an amplifier stage output of the amplifier stage. The radio frequency generator system further includes a matching network that is connected to the amplifier stage output of the amplifier stage and is configured to set a predefined impedance for the amplifier stage output of the amplifier stage, the impedance between the amplifier stage output and the matching network being unequal to 50 ohms. The radio frequency generator system also includes a plasma process impedance acquisition unit that is configured to acquire a complex-valued impedance of the plasma process. The radio frequency generator system further includes a control unit which is connected to the plasma process impedance acquisition unit for signal transmission and is configured to (e.g., includes circuitry programmed to) control the signal generator unit, the amplifier stage and/or the matching network based on the acquired complex-valued impedance of the plasma process.

Embodiments of the present disclosure also provide a method of exciting a plasma for a plasma process. In an embodiment, the method includes the steps or actions of:
generating at least three radio frequency signals having different frequencies by a signal generator unit;
outputting the radio frequency signals through a shared signal generator output of the signal generator unit;
amplifying the radio frequency signals by a broadband amplifier stage; and
outputting amplified radio frequency signals at an amplifier stage output of the amplifier stage,
wherein a predefined impedance for the amplifier stage output of the amplifier stage is set by a matching network, wherein the impedance between the amplifier stage output and the matching network is unequal to 50 ohms,
wherein a complex-valued impedance of the plasma process is acquired by a plasma process impedance acquisition unit, and
wherein the signal generator unit, the amplifier stage and/or the matching network is/are controlled based on the acquired complex-valued impedance of the plasma process.

One fundamental idea of the present technology is to acquire the complex-valued impedance of the plasma process, for example in real time, and to use this to control the plasma process, for example likewise in real time. For controlling the plasma process, the components of the radio frequency generator system can be controlled appropriately in order to provide the radio frequency signals necessary for the excitation of the plasma process as desired. Since the amplifier stage and/or the matching network can also be controlled in addition to the signal generator unit, the amplification of the radio frequency signals and/or the adjustment can therefore also be appropriately controlled in order to increase efficiency.

For this purpose, the matching network is low-loss, and it is not provided in a 50-ohm environment. For example, the plasma impedance is between 5 ohms and 10 ohms, i.e. less than 50 ohms, and the impedance between the amplifier stage output and the matching network may be 2 ohms. The matching network serves to protect the upstream amplifier stage and the upstream signal generator unit, since the matching network is provided between the amplifier stage and a downstream plasma chamber, in which the plasma is excited.

In an embodiment, the broadband amplifier stage comprises at least one radio frequency amplifier, for example a plurality of radio frequency amplifiers for different frequency ranges, to allow the broadband amplifier stage to be implemented cost-effectively. The broadband amplifier stage comprises at least the three different frequencies of the at least three radio frequency signals generated by the signal generator unit. The use of the broadband amplifier stage makes it possible to incorporate multiples of the fundamental frequency to generate complex signal shapes for excitation of the plasma.

To generate the at least three radio frequency signals, the signal generator unit comprises, for example, at least one signal generator, for example at least three signal generators. In this respect, each of the radio frequency signals may have a respective signal generator assigned to it. If a plurality of signal generators are provided, output lines that lead from the plurality of signal generators are connected to each other, for example via an adder, with the one shared signal generator output being provided. Alternatively, only one signal generator may be provided, the output signal of which is divided and fed to frequency shifters in order to obtain the at least three radio frequency signals having different frequencies. Frequency dividers are provided, for example, to provide the at least three radio frequency signals having different frequencies. This means that the at least three radio frequency signals have a respective division ratio to one another.

One aspect provides, for example, that a first radio frequency signal having a first frequency, a second radio frequency signal having a second frequency, and a third radio frequency signal having a third frequency are provided, the third frequency being three times the first frequency and twice the second frequency. In this respect, the first radio frequency signal and the second radio frequency signal each have a frequency that is a part of the frequency of the third radio frequency signal. The different frequencies can be realized using a signal generator the output signal of which is split into three signals, two of which are processed using different frequency dividers, for example a 2:1 frequency divider and a 3:1 frequency divider. For example, the third radio frequency signal has a third frequency of 40.68 MHz, whereas the first radio frequency signal has a first frequency of 13.56 MHz, i.e. one third of the third frequency, and the second radio frequency signal has a second frequency of 20.34 MHz, i.e. half of the third frequency.

A further aspect provides that the signal generator unit, for example, is configured to adjust the frequency of each of the at least three radio frequency signals individually and independently of the other radio frequency signals. This is possible for example if the signal generator unit includes a plurality of signal generators that can be controlled individually, with their output signals corresponding to the radio frequency signals provided through the shared signal generator output. As an alternative, frequency shifters (rather than fixed frequency dividers) may be provided, which are appropriately controlled in order to change the frequency of each of the at least three radio frequency signals. Since each of the at least three radio frequency signals may have a signal generator or a frequency shifter assigned to it, the frequency of the respective radio frequency signal can be adjusted individually and independently of the other radio frequency signals.

For example, the signal generator unit is configured to adjust the amplitude and/or phase of each of the at least three radio frequency signals individually and independently of the other radio frequency signals. This is possible for example if the signal generator unit includes a plurality of signal generators that can be controlled individually, that is, with regard to amplitude and/or phase. Alternatively, provision may be made that a phase shifter and/or an amplifier or attenuator is/are provided in the signal paths emanating from the signal generator in order to adjust the amplitude and/or the phase of the radio frequency signals individually and independently of one another.

Generally, the signal generator unit may comprise, for example, a field programmable gate array (FPGA), that is, an integrated circuit, for example wherein the signal generator unit is configured to perform direct digital synthesis (DDS) to generate the at least three radio frequency signals having different frequencies.

In an embodiment, the matching network may comprise at least one adjustable capacitor, wherein the control unit includes circuitry configured to adjust the capacitance of the adjustable capacitor. A network of capacitors may be provided which can be connected in order to adjust the capacitance of the matching network. In this respect, no motor is required to adjust the capacitance. Alternatively or additionally, it may be provided that the matching network comprises an adjustable inductor and/or an adjustable reactor, that is, for example, a plurality of inductors or reactors that can be connected.

According to a further aspect, the plasma process impedance acquisition unit comprises, for example, a directional coupler configured to separate forward traveling waves and backward traveling waves from each other, and a measuring unit configured to acquire a forward power of the forward traveling waves and a reflected power of the backward traveling waves. The complex-valued impedance of the plasma process can be acquired using the forward power and the reflected power. In this respect, the control unit includes circuitry configured to control the signal generator unit, the amplifier stage and/or the matching network based on the acquired forward power of the forward traveling waves and the acquired reflected power of the backward traveling waves. The respective power, that is, the forward power and the reflected power, can be determined for each of the radio frequency signals, for example also for mixed products of the radio frequency signals. A respective measuring unit, also referred to as a detector, may be provided for the forward power and the reflected power, that is, for the forward traveling waves and the backward traveling waves. For this purpose, the measuring units are connected to appropriate ports of the directional coupler, for the forward traveling waves and, respectively, the backward traveling waves coupled out by the directional coupler to be passed on to the appropriate measuring unit. Scattering parameters may be determined, for example a complex value that represents the magnitude and angle, i.e. the amplitude and phase. In this respect, the amplitude and phase can be measured by the respective measuring unit in order to determine the corresponding power in this way.

In an embodiment, the plasma process impedance acquisition unit comprises at least one sensor configured to measure a voltage, a current and a phase between the voltage and the current. In addition to the impedance of the plasma process, the current and the voltage can be acquired, as well as the phase between the voltage and the current. The at least one sensor may be integrated in a printed circuit board, thereby providing an appropriately compact structure.

In an embodiment, the radio frequency generator system may include an input interface that is configured to receive at least one radio frequency signal from an external signal source, for example wherein a bypass is provided between the input interface and the amplifier stage. An external radio frequency signal can thus be fed to the radio frequency generator system, based on which the at least three radio frequency signals having the different frequencies are generated. But it is also possible to provide the at least three radio frequency signals having the different frequencies through the input interface, which are amplified by the broadband amplifier stage. In this case, a bypass is provided between the input interface and the amplifier stage so that it is possible to switch between the internal signal generator unit and the input interface. In other words, the amplifier stage may be in communication with either the internal signal generator unit or the input interface to obtain the at least three radio frequency signals having different frequencies that are amplified.

A further aspect provides that the control unit includes, for example, a control unit interface, by which control signals can be received. In an embodiment, the control signals may be a start signal and/or a stop signal. A frequency, a signal shape, a power, an amplitude and/or a phase may also be specified or controlled by the control signals. The control unit interface may be an Ethernet interface, for example EtherCAT, i.e. “Ethernet for Control Automation Technology”.

In an embodiment, the signal generator unit may be configured to carry out an adjustment of the voltage waveform in order to generate the radio frequency signals, that is, the at least three radio frequency signals having the different frequencies. The adjustment of the voltage waveform is also referred to as voltage waveform tailoring. By adjusting the voltage waveform of the radio frequency signals, a more precise influencing of the plasma to be excited can be achieved, since pulse cycles, pulse shape or edge shape can be adjusted accordingly.

Embodiments of the present disclosure also provide a plasma generation system for plasma excitation for a plasma process, including a plasma chamber and a radio frequency generator system according to any one or the embodiments described above. The radio frequency generator system is connected to at least one electrode that is arranged in the plasma chamber. The advantages mentioned above apply analogously to the plasma generation system.

One aspect provides that the plasma process impedance acquisition unit, for example, is arranged closer to the at least one electrode than to the matching network. The plasma process impedance acquisition unit is therefore directly associated with the plasma chamber in which the at least one electrode is arranged, which is why the impedance of the plasma process can be acquired. In an embodiment, the plasma process impedance acquisition unit is provided between the matching network and the plasma chamber.

In this respect, the plasma process impedance acquisition unit is provided at the output of the radio frequency generator system, by which the plasma chamber is connected to the radio frequency generator system. The forward power and the reflected power of the respective waves of the radio frequency signals are therefore acquired at the output of the radio frequency generator system.

Basically, an exact real-time acquisition of the complex impedance of the plasma process is effected in the immediate vicinity of the plasma chamber, which allows a fast control of the RF power in a controlled manner.

In addition, the use of the broadband amplifier stage makes it possible to also incorporate multiples of a fundamental frequency or parts of a fundamental frequency to generate complex signal shapes to control the plasma, that is, the so-called “voltage waveform tailoring,” VWT.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 shows a schematic illustration of a plasma generation system with a radio frequency generator system according to a an embodiment of the present disclosure;

FIG. 2 shows a schematic illustration of a plasma generation system with a radio frequency generator system according to another embodiment of the present disclosure; and

FIG. 3 shows an overview of a representative method according to an embodiment of the present disclosure for exciting a plasma for a plasma process.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

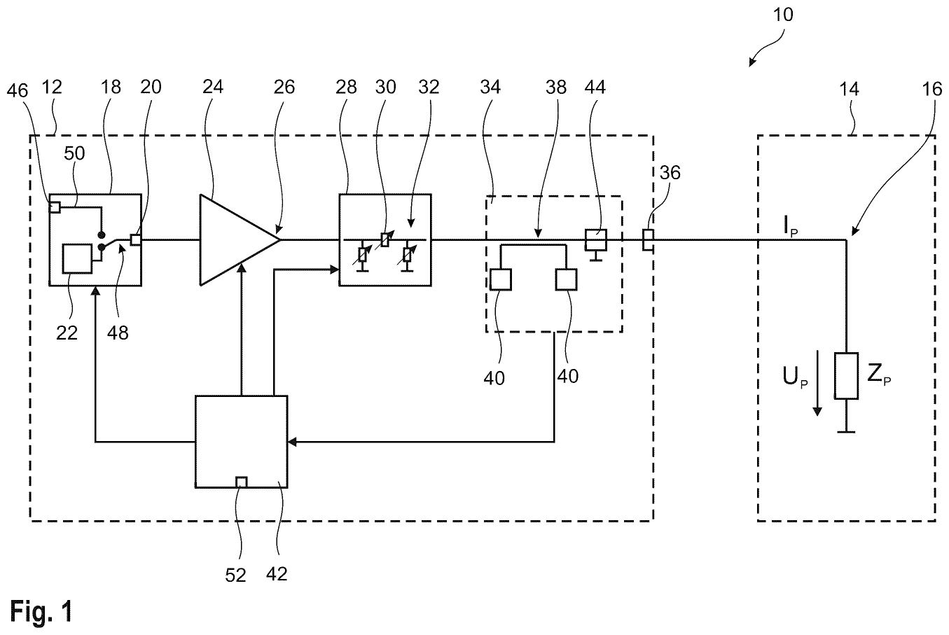

FIG. 1 shows an example embodiment of a plasma generation system 10 for plasma excitation for a plasma process, which comprises a radio frequency generator system 12 and a plasma chamber 14 that is connected to the radio frequency generator system 12 and in which at least one electrode 16 is provided by which the plasma is generated.

The radio frequency generator system 12 generates radio frequency signals which are passed on to the electrode 16 to generate the plasma. In an embodiment, the radio frequency generator system 12 includes a signal generator unit 18, which can generate at least three radio frequency signals having different frequencies, which are output at a shared signal generator output 20. In the embodiment shown in FIG. 1, the signal generator unit 18 includes a signal generator 22, for example an FPGA.

Connected to the signal generator output 20 is a broadband amplifier stage 24, which receives the at least three radio frequency signals having different frequencies from the signal generator unit 18 in order to amplify them so that amplified radio frequency signals are generated, which are output at an amplifier stage output 26 of the amplifier stage 24.

Connected to the amplifier stage output 26 of the amplifier stage 24 is a matching network 28 which comprises at least one adjustable capacitor 30, for example a network 32 of a plurality of adjustable capacitors 30, for example connectable capacitors. Alternatively or additionally, the matching network 28 may include a plurality of adjustable inductors and/or reactors that are connectable to adjust the inductance or reactance. Generally described, the matching network 28 sets a predefined impedance for the amplifier stage output 26 of the amplifier stage 24 so that the impedance between the amplifier stage output 26 and the matching network 28 is unequal (e.g., is not equal) to 50 ohms.

The radio frequency generator system 12 may also comprises a plasma process impedance acquisition unit 34 that is arranged downstream of the matching network 28, for example upstream of an output 36 of the radio frequency generator system 12. The plasma process impedance acquisition unit 34 comprises a directional coupler 38 and measuring units 40 that are coupled to the directional coupler 38. The directional coupler 38 separates forward traveling waves and backward traveling waves of the radio frequency signals from each other, which are then fed to the measuring units 40 to acquire the forward power of the forward traveling waves and the reflected power of the backward traveling waves. In an embodiment, the amplitude and the phase of the forward traveling waves and the backward traveling waves, respectively, are acquired in order to draw conclusions from this about the forward power and, respectively, the reflected power.

Based on the parameters acquired, that is, the forward power and the reflected power, a complex-valued impedance of the plasma process within the plasma chamber 14 can be acquired, which serves as a control parameter for the plasma process.

The radio frequency generator system 12 further includes a control unit 42 that is connected to the plasma process impedance acquisition unit 34 for signal transmission in order to obtain the acquired complex-valued impedance of the plasma process. On the basis of this, the control unit 42 can control the signal generator unit 18, the amplifier stage 24 and/or the matching network 28.

In order that the impedance of the plasma process within the plasma chamber 14 is acquired as precisely as possible, the plasma process impedance acquisition unit 34 is arranged closer to the at least one electrode 16 than to the matching network 28.

In addition, the plasma process impedance acquisition unit 34 may include at least one sensor 44 which can be used to sense a voltage UP of the plasma process, a current IP of the plasma process and a phase between the voltage UP of the plasma process and the current IP of the plasma process. In this respect, further parameters are acquired in order to characterize the plasma process.

The impedance of the plasma process determined by the forward power and the reflected power may be used as the main parameter for controlling the plasma process, with the current, the voltage and the phase between the voltage and the current serving as additional parameters for controlling the plasma process. In an embodiment, provision may be made for a desired voltage of the plasma process to be achieved, with the components of the radio frequency generator system 12 being controlled accordingly for this purpose, i.e. the signal generator unit 18, the amplifier stage 24 and/or the matching network 28.

When controlling the signal generator unit 18, the control unit 42 can adjust the frequency of each of the at least three radio frequency signals individually and independently of the other radio frequency signals. Similarly, the control unit 42 may control the signal generator unit 18 such that the amplitude and/or phase of each of the at least three radio frequency signals is adjusted individually and independently of the other radio frequency signals.

With respect to the broadband amplifier stage 24, the control unit 42 is adapted to adjust the amplification for each of the at least three radio frequency signals individually and independently of the other radio frequency signals by appropriately controlling the broadband amplifier stage 24. The control unit 42 is also adapted to control the matching network 28 in that at least one of the adjustable capacitors 30 is adjusted or connected. Alternatively or additionally, at least one of the adjustable inductors or reactors is adjusted or connected.

In one or more embodiments, the control unit 42 includes circuitry programmed to carry out the functionality or actions of the control unit 42 set forth herein.

In principle, the radio frequency generator system 12 may also include an input interface 46 by which at least a radio frequency signal from an external signal source can be supplied to the radio frequency generator system 12.

The broadband amplifier stage 24 is connected in a signal-transmitting manner to the signal generator unit 18 in a first operating mode and to the input interface 46 in a second operating mode. In other words, the broadband amplifier stage 24 is connected in a signal-transmitting manner to either the signal generator unit 18 or the input interface 46 in order to amplify the radio frequency signals generated by the signal generator unit 18 or the radio frequency signals received through the input interface 46. A switching unit 48 and a bypass 50 to the signal generator unit 18 are provided for switchover, by means of which the broadband amplifier stage 24 (in the second operating mode) is connected directly to the input interface 46 in a signal-transmitting manner. In this respect, the signal generator unit 18 is bridged appropriately by the bypass 50 in the second operating mode.

In an embodiment, the control unit 42 itself includes a control unit interface 52, via which control signals can be received which are processed, for example, by the control unit 42 in order to control the components of the radio frequency generator system 12, for example the signal generator unit 18. This allows, for example, the voltage waveform to be adjusted in order to ensure precise influencing of the plasma to be excited.

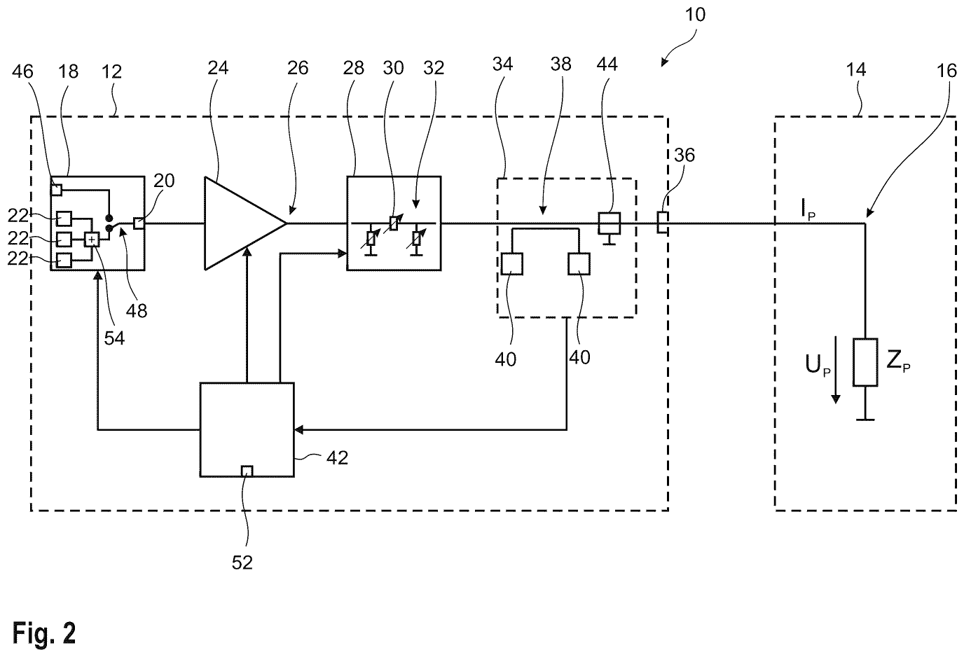

The embodiment shown in FIG. 2 differs from the embodiment shown in FIG. 1 in the configuration of the signal generator unit 18, since the signal generator unit 18 in FIG. 2 includes a plurality of signal generators 22, which are connected to the shared signal generator output 20 by an adder 54.

In the embodiment shown in FIG. 2, the control unit 42 controls the individual signal generators 22, for example the frequency, the amplitude and/or the phase of the radio frequency signals generated by the respective signal generator 22.

Generally described, the radio frequency generator system 12 can be used to generate a first radio frequency signal having a first frequency (e.g. 13.56 MHz), a second radio frequency signal having a second frequency (e.g. 20.34 MHz), and a third radio frequency signal having a third frequency (e.g. 40.68 MHz). For example, the third frequency is three times the first frequency and twice the second frequency.

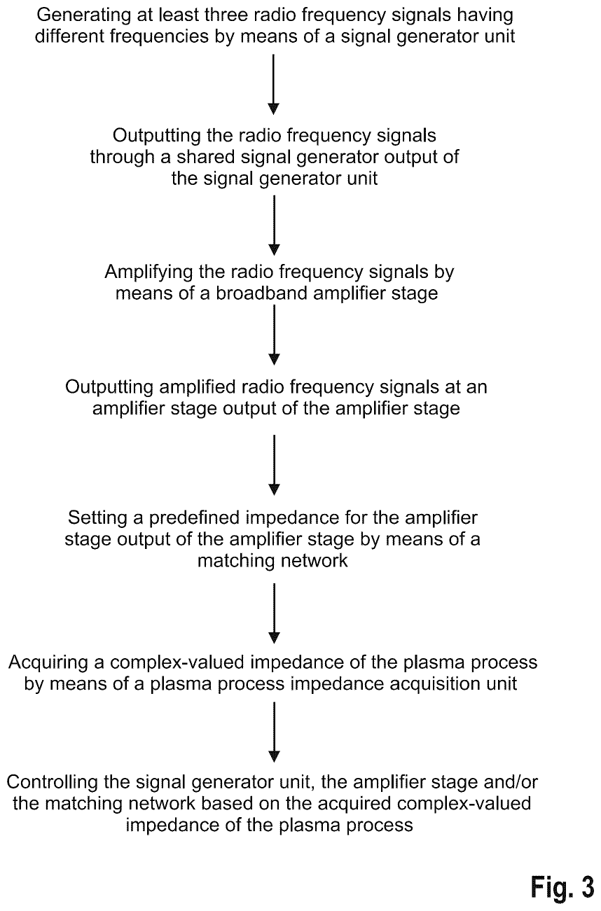

Using the plasma generation systems 10 shown in FIGS. 1 and 2, the method of exciting a plasma for a plasma process can be carried out, an example of which is shown in FIG. 3.

Here, in a first step S1, at least three radio frequency signals having different frequencies are generated by the signal generator unit 18.

In a second step S2, the radio frequency signals are output through the shared signal generator output 20 of the signal generator unit 18.

In a third step S3, the radio frequency signals are amplified by the broadband amplifier stage 24 to obtain amplified radio frequency signals.

In a fourth step S4, the amplified radio frequency signals are output at the amplifier stage output 26 of the amplifier stage 24.

The amplified radio frequency signals output through the amplifier stage output 26 of the amplifier stage 24 are passed on to the electrode 16 within the plasma chamber 14 to excite the plasma. Here, a specified impedance for the amplifier stage output 26 of the amplifier stage 24 is set by the matching network 28.

At the same time, the complex-valued impedance of the plasma process is acquired by the plasma process impedance acquisition unit 34, this being performed by the directional coupler 38 and the measuring units 40 in order to measure the forward power of the forward traveling waves and the reflected power of the backward traveling waves, based on which the complex-valued impedance of the plasma process is determined.

The complex-valued impedance of the plasma process is utilized as a control parameter so that the control unit 42 controls the signal generator unit 18, the amplifier stage 24 and/or the matching network 28 accordingly based on the complex-valued impedance of the plasma process.

The method, which can be carried out using the plasma generation system 10, for example the radio frequency generator system 12, allows efficient plasma excitation.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be used synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components of the system 10, etc., referenced above include circuitry programmed to carry out one or more steps of any of the methods disclosed herein. In an embodiment, one or more computer-readable media associated with or accessible by such circuitry contains computer readable instructions embodied thereon that, when executed by such circuitry, cause the component or circuitry to perform one or more steps of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuitry disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. While the stated range includes one or both of the limits, ranges excluding either or both of those included limits are also included in the disclosure

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. A radio frequency generator system for plasma excitation for a plasma process, comprising:
a signal generator unit configured to generate at least three radio frequency signals having different frequencies, wherein the signal generator unit has a shared signal generator output through which the radio frequency signals are output;
a broadband amplifier stage which is connected to the shared signal generator output and is configured to amplify the radio frequency signals to output amplified radio frequency signals at an amplifier stage output of the amplifier stage;
a matching network that is connected to the amplifier stage output of the amplifier stage and is configured to set a predefined impedance for the amplifier stage output of the amplifier stage, wherein the impedance between the amplifier stage output and the matching network is not equal to 50 ohms;
a plasma process impedance acquisition unit configured to acquire a complex-valued impedance of the plasma process; and
a control unit is connected to the plasma process impedance acquisition unit for signal transmission, wherein the control unit includes circuitry configured to control the signal generator unit, the amplifier stage and/or the matching network based on the acquired complex-valued impedance of the plasma process.

2. The radio frequency generator system according to claim 1, wherein a first radio frequency signal having a first frequency, a second radio frequency signal having a second frequency and a third radio frequency signal having a third frequency are provided, the third frequency being three times the first frequency and twice the second frequency.

3. The radio frequency generator system according to claim 1, wherein the signal generator unit is configured to adjust the frequency of each of the at least three radio frequency signals individually and independently of the other radio frequency signals.

4. The radio frequency generator system according to claim 1, wherein the signal generator unit is configured to adjust the amplitude and/or phase of each of the at least three radio frequency signals individually and independently of the other radio frequency signals.

5. The radio frequency generator system according to claim 1, wherein the matching network comprises at least one adjustable capacitor, an adjustable inductor and/or an adjustable reactor, wherein the control unit is configured to adjust the capacitance of the adjustable capacitor, the inductance of the adjustable inductor and/or the reactance of the adjustable reactor.

6. The radio frequency generator system according to claim 1, wherein the plasma process impedance acquisition unit comprises a directional coupler configured to separate forward traveling waves and backward traveling waves from each other, and a measuring unit configured to acquire a forward power of the forward traveling waves and a reflected power of the backward traveling waves.

7. The radio frequency generator system according to claim 1, wherein the plasma process impedance acquisition unit comprises at least one sensor configured to measure a voltage, a current and a phase between the voltage and the current.

8. The radio frequency generator system according to claim 1, further comprising an input interface configured to receive at least one radio frequency signal from an external signal source.

9. The radio frequency generator system according to claim 8, wherein a bypass is provided between the input interface and the amplifier stage.

10. The radio frequency generator system according to claim 1, wherein the control unit includes a control unit interface by which control signals can be received.

11. The radio frequency generator system according to claim 1, wherein the signal generator unit is configured to carry out an adjustment of the voltage waveform in order to generate the radio frequency signals.

12. A plasma generation system for plasma excitation for a plasma process, comprising a plasma chamber and a radio frequency generator system according to claim 1, wherein the radio frequency generator system is connected to at least one electrode that is arranged in the plasma chamber.

13. The plasma generation system according to claim 12, wherein the plasma process impedance acquisition unit is arranged closer to the at least one electrode than to the matching network.

14. A method of exciting a plasma for a plasma process, comprising:
generating at least three radio frequency signals having different frequencies by a signal generator unit;
outputting the radio frequency signals through a shared signal generator output of the signal generator unit;
amplifying the radio frequency signals by a broadband amplifier stage; and
outputting amplified radio frequency signals at an amplifier stage output of the amplifier stage,
wherein a predefined impedance for the amplifier stage output of the amplifier stage is set by a matching network, wherein the impedance between the amplifier stage output and the matching network is not equal to 50 ohms,
wherein a complex-valued impedance of the plasma process is acquired by a plasma process impedance acquisition unit, and
wherein the signal generator unit, the amplifier stage and/or the matching network is/are controlled based on the acquired complex-valued impedance of the plasma process.
